(19) United States
(12) Patent Application Publication
(10) Pub. No.: US 2012/0266958 A1
(43) Pub. Date: Oct. 25, 2012

(54) METHODS OF FORMING RUTHENIUM-GROUP IIIA ALLOYS

(75) Inventors: Serdar Aksu, San Jose, CA (US); Sarah Lastella, Sunnyvale, CA (US); Alan Kleiman-Shwarsctein, Santa Clara, CA (US); Shirish Pethe, Santa Clara, CA (US); Mustafa Pinarbasi, Morgan Hill, CA (US)

(73) Assignee: SoloPower, Inc., San Jose, CA (US)

(21) Appl. No.: 13/457,224

(22) Filed: Apr. 26, 2012

Related U.S. Application Data
(63) Continuation-in-part of application No. 13/149,381, filed on May 31, 2011.
Application No. 13/149,381 is a continuation of application No. 12/267,488, filed on Nov. 7, 2008, now Pat. No. 7,951,280.

(51) Int. Cl. H01L 31/18; C22C 5/04; C22C 30/00; H01L 31/0216

(52) U.S. Cl. 136/262; 136/252; 438/95; 438/62; 420/462; 420/580; 257/E31.027

(57) ABSTRACT

Described are embodiments including an apparatus that provides a thin film solar cell base structure for a photovoltaic device, a method of manufacturing a photovoltaic device, a roll to roll method of manufacturing a thin film solar cell base structure, and a ruthenium alloy sheet material.

### CROSS-REFERENCE TO RELATED APPLICATION

This application is a Continuation in Part of U.S. patent application Ser. No. 13/149,381, filed May 31, 2011, which is a Continuation of U.S. patent application Ser. No. 12/267,488, filed Nov. 7, 2008, now U.S. Pat. No. 7,951,280 issued May 31, 2011, which are incorporated herein by reference.

### BACKGROUND

### Description of the Related Art

Thin film solar cells have attracted much attention lately because of their potential low cost. Thin film solar cells may employ, as their light absorbing layer or absorber, polycrystalline silicon, amorphous silicon, cadmium telluride (CdTe), copper indium gallium selenide (sulfide) (CIGS(S)), etc. The processing methods used for the preparation of thin film solar cell absorber layers can generally be classified as dry and wet processes. The dry processes include physical vapor deposition (PVD) and chemical vapor deposition (CVD) techniques, which are usually well developed, however, expensive. Wet processes include ink spraying or printing, chemical bath deposition (CBD) and electrochemical deposition (ED), also called electrodeposition or electroplating. Among these methods, CBD is popular for the preparation of some n-type semiconductor films like CdS, ZnSe, In—Se, etc. In ink deposition processes, inks comprising nano-particles dispersed in a solvent are deposited on a substrate. When the solvent evaporates away, it leaves behind a precursor layer comprising the nano-particles. The precursor layer is then sintered at high temperatures to form the absorber.

Electrochemical deposition techniques can provide thin precursor films which may then be converted into solar cell absorbers. One recent application of electroplated copper (Cu), indium (In) and gallium (Ga) films is in the formation of Cu(In,Ga)(Se,S)₂ or CIGS(S) type layers, which are the most advanced compound absorbers for polycrystalline thin film solar cells. It should be noted that the notation (In, Ga) means all compositions from 100% In and 0% Ga to 0% In and 100% Ga. Similarly, (Se,S) means all compositions from 100% Se and 0% S to 0% Se and 100% S. Applying electrodeposition to the formation of a CIGS(S) type absorber layer may involve a two-stage or two-step processing approach comprising a precursor deposition step and a reaction step. A thin In layer, for example, may be electroplated on a Cu layer. A thin Ga film may then be formed on the In layer to form a Cu/In/Ga stack precursor. The Cu/In/Ga precursor stack thus obtained may then be reacted with selenium (Se) to form a CIGS absorber. Further reaction with sulfur (S) would form a CIGS(S) layer. The CIGS(S) absorber may be used in the fabrication of thin film Group IBIIIAVIA compound solar cells with a structure of “contact/CIGS(S)/buffer layer/TCO”, where the contact is a metallic layer such as a molybdenum (Mo) layer, the buffer layer is a thin transparent film such as a cadmium sulfide (CdS) film and transparent conductive oxide (TCO) is a transparent conductive layer such as a zinc oxide (ZnO) and/or an indium tin oxide (ITO) layer.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)2 is formed on the conductive Mo film. The substrate 11 and the contact layer 12 form a base layer 13. Although there are other methods, Cu(In,Ga)(S,Se)2 type compound thin films are typically formed by a two-stage process where the components (components being Cu, In, Ga, Se and S) of the Cu(In,Ga)(S,Se)2 material are first deposited onto the substrate or a contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack, is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate, such as glass or transparent polymeric foil, and then depositing the Cu(In,Ga)(S,Se)2 absorber film, and finally forming an ohmic contact to the device by a conductive layer. In the superstrate-type structure light enters the device from the transparent superstrate side.

In a thin film solar cell employing a Group IBIIIAVIA compound absorber such as CIGS(S), the cell efficiency is a strong function of the molar ratio of IB/IIIA. If there are more than one Group IIIA materials in the composition, the relative amounts or molar ratios of these IIIA elements also affect the properties. For a Cu(In,Ga)(S,Se)₂ or CIGS(S) absorber layer, for example, the efficiency of the device is a function of the molar ratio of Cu/(In+Ga), where Cu is the Group IB element and Ga and In are the Group IIIA elements. Furthermore, some of the important parameters of the cell, such as its open circuit voltage, short circuit current and fill factor vary with the molar ratio of the IIIA elements, i.e. the Ga/(Ga+In) molar ratio. In general, for good device performance Cu/(In+Ga) molar ratio is kept at or below 1.0. For ratios close to or higher than 1.0, a low resistance copper selenide phase may form, which may introduce electrical shorts within the solar cells. As the Ga/(Ga+In) molar ratio increases, on the other hand, the optical bandgap of the absorber layer increases and therefore the open circuit voltage of the solar cell increases while the short circuit current typically may decrease. It is important for a thin film deposition process to have the capability of controlling both the molar ratio of IB/IIIA, and the molar ratios of the Group IIIA components in the composition. Therefore, if electrodeposition is used to introduce the Ga into the film composition, it is essential that the electroplated Ga films have smooth morphology and be free of defects such as pinholes. It should be noted that the typical thickness of Ga layers to be electroplated for CIGS(S) absorber formation is in the range of 50-300 nm and many prior art electroplated Ga layers display a peak-to-valley surface roughness in the range of 50-500nm, which means that these films are very thick in some areas and very thin in others.

In an application of electroplated Ga layers to solar cell fabrication, the Ga layer may be electroplated to form precursor stacks with structures such as Cu/In/Ga, Cu/Ga/In, etc. These stacks may then be reacted at high temperature (typically in the range of 400-600° C.) with a Group VIA material such as Se and S to form a CIGS(S) absorber layer. The absorber layer may then be further processed to construct a solar cell. US Patent Application with publication No. 20070272558, entitled “Efficient Gallium Thin Film Electroplating Methods and Chemistries” filed by the applicants of this application and incorporated herein by reference, discloses new methods and chemistries to deposit Ga films with high plating efficiency. Other work on electrodeposition of Ga includes the publication by S. Sundararajan and T. Bhat (J. Less Common Metals, vol. 11, p. 360, 1966) who utilized electrolytes with a pH value varying between 0 and 5. Other researchers investigated Ga deposition out of high pH solutions comprising water and/or glycerol. Bockris and Enyo, for example, used an alkaline electrolyte containing Ga-chloride and NaOH (J. Electrochemical Society, vol. 109, p. 48, 1962), whereas, P. Andreoli et al.(Journal of Electroanalytical Chemistry, vol. 385, page.265, 1995) studied an electrolyte comprising KOH and Ga-chloride. While some of these previous works used very corrosive solutions, i.e., pH=15, most of them were carried out under low plating efficiencies in low pH electrolytes, the plating efficiencies being typically 20% or lower. Glycerol, due to its high boiling temperature has also been used in high temperature (>100° C.) preparation of electrodeposition chemistries to plate molten globules of Ga-In alloys (see e.g. U.S. Pat. No. 2,931,758). Although, glycerol-based plating solutions may be adequate to obtain Ga deposits in the form of thick molten globules such deposits cannot be used in the formation solar cell absorbers such as thin film CIGS(S) compounds. From the foregoing, there is a need to develop Ga electrolytes and electrodeposition methods to generate smooth, uniform and defect-free Ga thin films with high plating efficiencies on surfaces of varying chemical composition. This way Ga layers may be electroplated onto different cathode surfaces for electronics applications, specifically for the fabrication of high quality CIGS(S) type thin film solar cell absorbers.

### SUMMARY

Described are embodiments including an apparatus that provides a thin film solar cell base structure for a photovoltaic device, a method of manufacturing a photovoltaic device, a roll to roll method of manufacturing a thin film solar cell base structure, and a ruthenium alloy sheet material.

In one embodiment is described an apparatus that provides a thin film solar cell base structure for a photovoltaic device, comprising: a conductive substrate, wherein the conductive substrate is a sheet shaped substrate including an upper surface; a ruthenium-Group IIIA alloy layer formed over the upper surface of the conductive substrate, the ruthenium-Group IIIA alloy layer including ruthenium (Ru) and a Group IIIA material; and an absorber layer formed over the ruthenium-Group IIIA alloy layer, thereby creating the thin film solar cell base structure.

In another embodiment is described a method of manufacturing a photovoltaic device, comprising: providing a conductive substrate, wherein the conductive substrate is a sheet shaped substrate including an upper surface; forming a ruthenium-Group IIIA alloy layer over the upper surface of the conductive substrate, the ruthenium-Group IIIA alloy layer including ruthenium (Ru) and a Group IIIA material; forming a CIGS absorber layer over the ruthenium-Group IIIA alloy layer; and reacting the CIGS absorber layer to form the photovoltaic device

In a further embodiment is described A roll to roll method of manufacturing a thin film solar cell base structure, comprising: providing a conductive substrate having a top surface, wherein the conductive substrate is a sheet shaped substrate having a top surface; advancing the conductive substrate through a process station; and forming a ruthenium-Group IIIA alloy layer over the top surface of the conductive substrate as the substrate advanced through the process station, to create the thin film solar cell base structure, the alloy layer including ruthenium (Ru) and a Group IIIA material.

In yet a further embodiment is described an ruthenium alloy sheet material comprising, by molar percentage: 1-50% of gallium (Ga); no more than 5% of any other impurity; and a remaining molar percentage of ruthenium (Ru).

### BRIEF DESCRIPTION OF THE DRAWINGS

The above and other embodiments will now be described with reference to the drawings in which:

FIG. 1 a schematic illustration of a solar cell;

FIG. 2 is a schematic illustration of a gallium film electrodeposited on a conductive surface from an electrodeposition solution;

FIG. 3 is schematic illustration of an embodiment of a base including a Ru-Group IIIA material alloy layer;

FIG. 4 is a schematic illustration of an embodiment of a roll-to-roll system to manufacture the base shown in FIG. 3.

FIG. 5 is a schematic illustration of a solar cell using the base shown in FIG. 3.

FIG. 6 is an XRD spectrum illustrating the formation of RuGa alloy phase as described in Example 1;

FIG. 7 is an XRD spectrum illustrating the formation of RuGa₃ and RuGa alloy phases as described in Example 1;

FIG. 8 is an XRD spectrum illustrating the formation of RuGa₃ alloy phase as described in Example 2;

FIG. 9A is an XRD spectrum illustrating the formation of RuIn₃ alloy phase as described in Example 3;

FIG. 9B is an XRD spectrum illustrating the preferential formation of RuGa₃ alloy phase over RuIn₃ alloy phase as described in Example 3;

FIG. 10A is an XRD spectrum illustrating the formation of RuGa₃ alloy phase in Se-poor conditions as described in Example 4;

FIG. 10B is an XRD spectrum illustrating the formation of RuGa alloy phase and CIGS in Se-rich conditions as described in Example 5;

FIG. 11 is a flow chart illustrating the process flow of Example 6; and

FIG. 12 is a flow chart illustrating the process flow of Example 7.

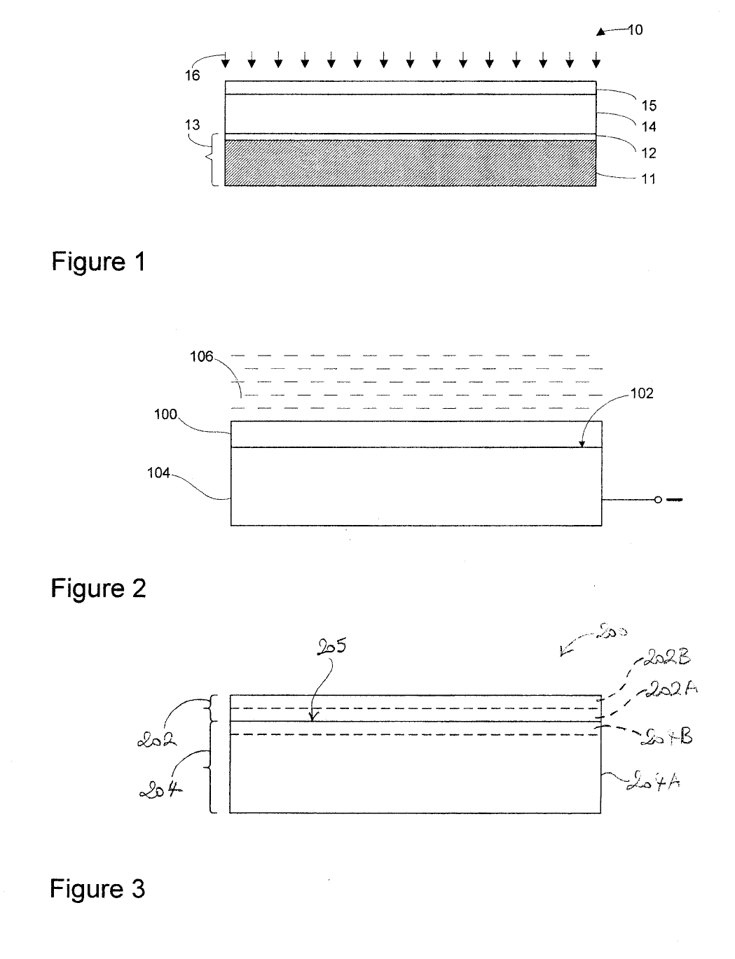

### DETAILED DESCRIPTION OF THE PREFERRED EMBODIMENTS

The embodiments described herein provide methods and electrodeposition solutions or electrolytes to electrodeposit uniform, smooth and repeatable gallium (Ga) films. Through the use of various aspects of the embodiments it is possible to form micron or sub-micron thick Ga films on conductive surfaces from solutions mixed with aqueous and organic solvents such as alcohols. The embodiments may be used to form gallium films for manufacturing solar cell absorbers. Electrodeposition solutions of the embodiments may be used at very low temperatures to improve the surface morphology of electroplated Ga films.

FIG. 2 shows an exemplary gallium thin film 100 or layer electrodeposited on a surface 102 of a conductive layer 104 from an electrodeposition solution 106 using an electrodeposition method. The gallium thin film 100 may be a part of a precursor stack, which may include indium and copper layers. The conductive layer 104 may be a solar cell base comprising a substrate and a contact layer deposited on the substrate, or a precursor layer including at least one of a gallium layer, indium layer and copper layer formed on the base. During the electrodeposition process, the conductive layer 104 is brought into contact with the electrodeposition solution 106 and negatively polarized with respect to a positively polarized electrode (not shown) that is also in contact with the electrodeposition solution. A typical conductive layer 104 used by embodiments comprise at least one of Cu, Ga, In, Mo, Ru, Ir and Os.

Gallium electrodeposition electrolytes and electrodeposition methods for solar cell manufacturing processes have many more stringent and special requirements than the electrodeposition methods and solutions employed for many other commonly plated metals such as Cu, Ni, Co, Pb, Sn, Ag, Au, Pt, and their alloys, etc. This stems from the facts that; i) Ga is one of the lowest melting point metals in existence, with a melting point of about 30° C., ii) Ga has a high negative electrodeposition potential and thus Ga electrodeposition efficiency is naturally low since high electrodeposition potentials cause hydrogen generation, in addition to Ga deposition, at the cathode surface in aqueous electrolytes, iii) hydrogen bubbles generated on a cathode surface form defects such as un-deposited regions unless such bubbles could immediately be removed from the surface, iv) Ga has a tendency to form low temperature melting alloys with many alloy-partner materials such as In, Cu, Ag, Pb, Sn, etc. Furthermore, such alloys may form during electrodeposition of Ga onto surfaces comprising any of such alloy-partner materials.

Electrodeposition solutions employing glycerol are very viscous and difficult to handle. The viscosity of glycerol at room temperature is 1500 centipoise (cP) compared to the viscosity of water, which is 1 cP. Gas bubbles such as hydrogen bubbles formed on the electroplated (cathode) surface during Ga plating in viscous electrolytes cannot be easily removed from that surface and therefore cause voids and other defects in the electrodeposited films. Such defects may be acceptable for some applications of thick electrodeposited Ga globules. However, they cannot be tolerated in electronic device applications such as solar cell absorber formation applications where they cause compositional non-uniformities, morphological non-uniformities, and pinholes etc., all of which negatively impact the device performance.

Glycerol based plating solutions become more viscous as their temperature is lowered and therefore the problems cited above may get worse at lower temperatures. One other important point about the electrodeposition process for Ga is its sensitivity to the nature of the substrate surface on which the electrodeposition is performed. For example, to form a Cu/In/Ga precursor stack, the Ga film needs to be electrodeposited on an In surface. To form a Cu/Ga/In precursor stack, on the other hand, Ga plating needs to be performed on a Cu surface. One Ga electrodeposition solution that performs well for plating Ga on a Cu surface may not perform well for electrodepositing Ga on an In surface because the electrodeposition efficiency of Ga on one surface may be very different from its electrodeposition efficiency on another surface.

As mentioned above, gallium is a low melting point material with a melting temperature of around 30° C. As a result, when electrodeposited out of aqueous electrodeposition solutions kept at about room temperature (20-25° C.), it often forms rough films comprising molten surface features, especially at high electrodeposition current densities such as current densities greater than about 5 mA/cm². This is because even though the electrodeposition solution may be at a temperature lower than the melting point of Ga, the local temperature on the cathode surface may actually exceed this melting point due to the heat generated by the electrodeposition current. As further mentioned above, when Ga is electrodeposited on surfaces of materials that easily form alloys with Ga, molten droplets of Ga alloys with low melting temperatures may be formed on such surfaces. If the Ga film is electrodeposited over In and/or Cu, the local heating and Ga melting may actually promote alloying between the plated Ga film and the underlying In and/or Cu because there are low melting alloy phases between Ga and these materials such as In-Ga alloy phases and CuGa₂ alloy phase. As a result, the surface roughness of the deposit may further be increased due to the above mentioned reaction and the formation of molten alloy phases. For example, Mehlin et al. (Z. Naturforsch, vol. 49b, p. 1597 (1994)) attributed the rough morphology of their electroplated Ga layers to the alloying of the electrodeposited Ga with the underlying Cu surface of the cathode and the formation of a molten CuGa₂ alloy.

Gallium may be electrodeposited from the electrodeposition solution at temperatures below −10° C., preferably below −20° C., most preferably below −30° C., so that local melting of the deposited Ga and its possible reaction with the materials on the cathode surface are avoided. Furthermore, at these low temperatures, the electrodeposition current densities may be increased to levels above 5 mA/cm², preferably above 10 mA/cm² and even above 20 mA/cm² without causing melting and/or alloying on the cathode surface. As a result, the electrodeposition rate and therefore the process throughput may be increased while, at the same time, the deposited film roughness is reduced. All of these benefits are important for the successful use of electrodeposited Ga layers in thin film solar cell manufacturing. For example, the melting point of methanol is −97° C. and the freezing point of a methanol/water mixture is a function of the ratio of methanol to water in the electrodeposition solution. A mixture of 75% methanol and 25% water, for instance, has a freezing point of −82° C. (−115° F.). This means that a Ga plating electrodeposition solution comprising 75% methanol and 25% water may be operated at a temperature as low as about −70-80° C., thus avoiding the melting, reaction and surface roughness problems described above.

The electrodeposition solution may be used to electroplate Ga thin films onto conductive surfaces with a considerably high electrodeposition efficiency of greater than 40%. The electrolyte solution may comprise water and an organic solvent with a room temperature viscosity of less than about 10 cP, preferably less than about 5 cP. Examples of such organic solvents include monohydroxyl alcohols such as methanol, ethanol, and isopropyl alcohol. These organic solvents also have very low freezing points.

As well known in the field of chemistry, an alcohol is defined to be a hydrocarbon derivative in which a hydroxyl group (—OH) is attached to a carbon atom of an alkyl or substituted alkyl group. If the alcohols have two (—OH) groups, such as ethylene glycol and propylene glycol, they are classified as diols or glycols. Glycerol or sugar alcohol has three (—OH) groups and a boiling point of 290° C. Glycols also have boiling points close to 200° C. Therefore, diols containing two (—OH) groups or other organic compounds containing 3 or more (—OH) groups may be useful for high temperature electrodeposition solutions. However, as explained before, such organic compounds have shortcomings including high viscosity giving rise to defectivity in the electrodeposited thin layers. Furthermore, the freezing point of glycerol is too high for the purpose of good quality thin film Ga electrodeposition. The viscosities of ethylene glycol, propylene glycol and diethylene glycol, which are all diols, are 16 cP, 40 cP and 32 cP, respectively. Their freezing points, on the other hand are about −13° C., −59° C. and −10° C., respectively. The viscosity and the freezing point of glycerol, which has three (—OH) groups, are 1500 cP and +18° C., respectively.

The electrodeposition solutions of one embodiment employ at least one monohydroxyl alcohol mixed with water as solvent. Monohydroxyl alcohols contain only one (—OH) or hydroxyl group and they include methanol, primary alcohols (such as ethanol, 1-propanol, isobutanol, 1-pentanol, 1-hexanol, 1-heptanol), secondary alcohols (such as isopropyl alcohol, 2-butanol, 2-methyl-2-butanol, 2-hexanol) and tertiary alcohols (such as tert-butanol, tert-amyl alcohol). The viscosities of monohydroxyl alcohols are typically below 10 cP, mostly below 5 cP, and their freezing points vary from −12° C. for 2-methyl-2-butanol, to -126° C. for 1-propanol. For example, viscosities of methanol, ethanol, 1-propanol, isobutanol, and isopropyl alcohol are 0.59 cP, 1.2 cP, 1.94 cP, 3.95 cP and 1.96 cP, respectively. Their respective freezing points are about −97° C., −114° C., −126° C., −108° C., and −89° C. As can be seen, these low viscosities and extremely low freezing temperatures are very desirable properties for thin Ga film electrodeposition.

The electrodeposition solution may further comprise an acid and/or a salt to control the pH and increase the solution conductivity. The electrodeposition solution may further include a Ga source dissolved in the electrolyte, such as Ga chloride, Ga sulfate, Ga sulfamate, Ga perchloride, Ga phosphate, Ga nitrate, etc. Additional inorganic and organic acids and their alkali metal (lithium (Li), sodium (Na), potassium (K), rubidium (Rb), caesium (Cs), and francium (Fr)) and/or alkali earth metal (beryllium (Be), magnesium (Mg), calcium (Ca), strontium (Sr), barium (Ba) and radium (Ra)) salts can be added to the electrodeposition solution to provide a buffer to stabilize the solution pH and to increase the conductivity of the electrodeposition solution. Concentrations of additional organic or inorganic acids and/or their alkali metal salts may not be high since the Ga salts in the composition also provide some of the ionic conduction. Acids such as sulfamic acid, citric acid, acetic acid, tartaric acid, maleic acid, boric acid, malonic acid, succinic acid, phosphoric acid, oxalic acid, formic acid, arsenic acid, benzoic acid, sulfuric acid, nitric acid, hydrochloric acid, and amino acids, may be used. As stated above, Li, Na, K, Rb, Cs, Be, Mg, Ca, Sr and Ba salts of these acids could be added along with the acid to adjust the pH, provide buffering and increase the electrodeposition solution conductivity. The electrodeposition solution pH range may be acidic or basic, but is preferably between 0 and 7.

The standard potential of Ga electrodeposition from aqueous electrolytes is E⁰_{Ga(III)/Ga}=−0.52 V. At this potential, the hydrogen evolution is aggressive, especially in an acidic aqueous solution. This is why the Ga electrodeposition processes typically display low electrodeposition efficiencies in aqueous acidic electrodeposition solutions. The mixture of an organic solvent described in embodiments reduces the amount of water in the electrodeposition solution and thereby reduces the tendency of hydrogen evolution from water and increases the Ga electrodeposition efficiency. Because of the low viscosity of the present electrodeposition solutions any hydrogen bubbles formed on the cathode surface are easily swept away reducing or eliminating defectivity in the electrodeposited Ga films. The embodiments will now be further described in the following example.

### EXAMPLE

To demonstrate the wide range of capabilities of the developed electrodeposition solution chemistries and techniques, the electrodeposition conditions of the Ga layers were widely varied using a factorial design with three factors and three levels. The exemplary solvent was a mixture of methanol and de-ionized water. The Ga source used was GaCl₃. Sulfamic acid was used in the electrodeposition solution to increase the ionic conductivity. The three factors that were changed in the experiments were: i) the volume ratios of methanol to water (M/W ratio), ii) the concentration of GaCl₃, and, iii) the concentration of the sulfamic acid. The pH was kept in the range of 1.3 and 2. All of the electrodeposition tests were carried out using a current density of 30 mA/cm² for 150 seconds without stirring the electrodeposition solutions. According to the Faraday's Law, the total charge passed to the cathodes was 4.5 Coulombs/cm². Therefore, a Ga film thickness of about 1.83 μm was expected if the Ga electrodeposition efficiency were 100%. The anode was a platinum (Pt) mesh. The cathode surface comprised a thin Cu layer. All of the solvent combinations resulted in clear miscible solutions of methanol and water. The thickness of the resultant Ga films was measured to evaluate the electrodeposition efficiencies.

M/W ratio in the present example (or more generally the organic solvent-to-water ratio of the electrodeposition solutions) was found to be an important variable. This ratio may be in the range of about 0.05-99, preferably in the range of about 0.1-10, more preferably in the range of about 0.2-5. The Ga concentration range in the electrolyte is preferably more than 0.1M. The maximum concentration of Ga is determined by the amount of Ga source dissolvable in the solvent with a specific M/W ratio, a typical concentration being in the range of 0.2-0.6M. The sulfamic acid concentration of the present example could be changed from zero to about 0.5M. However, the preferred range of the acid concentration in general is 0.05-0.2M. At higher concentrations of acid, for example over 0.5 M, the Ga electrodeposition efficiency was found to reduce to less than 10%. It should be noted that, within the preferred ranges of the above variables, Ga layers may be electrodeposited at electrodeposition efficiencies greater than 40% using the electrodeposition solutions or electrolytes.

The results of the above experiments may be summarized as follows: i) As the M/W ratio got higher, the electrodeposition efficiency also got higher; ii) as the sulfamic acid concentration became greater than 0.2M, the plating efficiency started to decline, and iii) in general higher Ga concentration in the electrodeposition solution yielded higher electrodeposition efficiencies.

The Ga source in the electrodeposition solution of the embodiments may comprise stock solutions prepared by dissolving Ga metal into their ionic forms as well as by dissolving soluble Ga salts, such as sulfates, chlorides, acetates, sulfamates, carbonates, nitrates, phosphates, oxides, perchlorates, and hydroxides in the solvent of the electrodeposition solution. As mentioned above, the polar organic solvents (monohydroxyl alcohols) are used in the formulation since they need to be miscible with water and dissolve certain amount of Ga salts, acids and their salts. Many primary, secondary or tertiary monohydroxyl alcohols may also be used in place of or in addition to the methanol used in the above example. These alcohols include but are not limited to ethanol, 1-propanol, isobutanol, 1-pentanol, 1-hexanol, 1-heptanol, isopropyl alcohol, 2-butanol, 2-methyl-2-butanol, 2-hexanol, tert-butanol and tert-amyl alcohol. The acids used in the embodiments may cover a wide range including sulfamic acid, acetic acid, citric acid, tartaric acid, maleic acid, boric acid, succinic acid, phosphoric acid, oxalic acid, formic acid, arsenic acid, benzoic acid, sulfuric acid, nitric acid, hydrochloric acid, and amino acids, etc. The concentrations of the acids and their alkali metal and alkali metal earth salts can be adjusted according to the pH requirements of the solutions. The solution pH values can be widely varied between acidic and basic ranges. The preferred range is a pH of 0 to 7. A more preferred range is between 1 and 3. For the pH values larger than 3, some acids with low pKₐ, i.e., maleic acid, oxalic acid, and phosphoric acid, may be preferred to both control the solution pH and at the same time complex the Ga³⁺ cations and avoid precipitation of Ga(OH)₃.

It should be noted that although the monohydrated alcohols constitute the preferred ingredients in the Ga electrodeposition solutions of embodiments, in certain embodiments some other organic solvents with appropriate viscosity and freezing point values may also be employed. These organic solvents include, but are not limited to acetonitrile (viscosity of about 0.35 cP and freezing point of about −45° C.), acetone (viscosity of about 0.32 cP and freezing point of about −95° C.), formaldehyde (viscosity of about 0.5 cP and freezing point of about −117° C.), and dimethylformimide (viscosity of about 0.9 cP and freezing point of about −61° C.), butyronitrile (viscosity of about 0.55 cP and freezing point of about −112° C.), docholoromethane (viscosity of about 0.41 cP and freezing point of about −97° C.), N-methyl-pyrrolidinone (freezing point of about −23° C.), γ-Butyrolactone (freezing point of about −43° C.), 1-2-Dimethoxy-ethane (viscosity of about 0.5 cP and freezing point of about −69° C.), and tetrahydrofuran (viscosity of about 0.5 cP and freezing point of about −108° C.). It should also be noted that other organic ingredients may also be added to the electrodeposition solution as long as they do not appreciably alter its desired properties described previously. These additional organic ingredients include, but are not limited to diols and alcohols with three (—OH) groups.

Both direct current (DC) and pulsed or variable voltage/current may be utilized during the electrochemical deposition processes in embodiments. The temperature of the electrodeposition solution may be in the range of −120° C. to +30° C. depending upon the nature of the organic solvent, the organic solvent-to-water volume ratio, and the nature of the cathode surface. If the cathode surface comprises materials that alloy easily at low temperature with Ga, then low temperatures such as temperatures in the range of −120° C. to −20° C., may be beneficially selected for the electrodeposition solution.

The electrodeposition solutions of the embodiments may comprise additional ingredients. These include, but are not limited to, grain refiners, surfactants, wetting agents, dopants, other metallic or non-metallic elements etc. For example, organic additives such as surfactants, suppressors, levelers, accelerators and the like may be included in the formulation to refine its grain structure and surface roughness. Organic additives include but are not limited to polyalkylene glycol type polymers, propane sulfonic acids, coumarin, saccharin, furfural, acrylonitrile, magenta dye, glue, SPS, starch, dextrose, and the like.

The following embodiments provide methods of forming ruthenium-Group IIIA alloys, preferably ruthenium-Group IIIA alloy thin films for thin film photovoltaic device or solar cell applications. For example, films of such alloys may be used as ohmic contacts for CIS, CIGS, CdTe, CuZnSnS₄ (CZTS) type semiconductor absorbers when placed between a semiconductor absorber and a metallic base such as a metallic substrate or a contact layer-substrate bi-layer.

The ruthenium-Group IIIA alloy can also serve as a barrier layer preventing impurities from the adjacent layers from diffusing into another layer. For example ruthenium-Group IIIA may prevent migration of Fe, Ni, Cr, Na, K, Al, Si amongst other elements from the substrate through such alloy into the absorber layer. The migration of Cu, In, Ga, Se from the absorber layer towards the substrate can be avoided by the ruthenium-Group IIIA barrier layer or a barrier layer containing such ruthenium-Group IIIA alloy.

The following embodiments provide a base or a substrate that enhances the efficiency and manufacturing yield of compound semiconductor solar cells or photovoltaic devices. One embodiment provides a solar cell including an alloy layer or alloy sheet material between an absorber layer and a conductive substrate. The alloy layer includes an alloy of ruthenium (Ru) and a Group IIIA material such as Ga or In metals. Another embodiment provides a method of forming a solar cell with an alloy layer including an alloy of ruthenium (Ru) and a Group IIIA material such as Ga or In metals. The alloy layer may be formed over a conductive substrate using deposition methods such as a physical vapor deposition (PVD) process, an electroplating (electrodeposition) process, a chemical vapor deposition process (CVD) or an atomic layer deposition (ALD) process. With these processes, both ruthenium and Group IIIA material may be co-deposited over a conductive substrate to form the alloy layer including Ru and Group IIIA material in desired compositions. After the co-deposition process, as deposited metals or alloy layer may or may not be annealed at an anneal process step. Alternatively, a stack including at least a Ru film and a Group IIIA material film may initially be deposited over the conductive substrate, and in a following anneal step, the stack is annealed to form the alloy layer.

The alloy layer may be manufactured using a roll-to-roll process so that the alloy layer is formed as the conductive substrate is advanced through an alloy layer process station. During the roll-to-roll process, the substrate is released from a substrate supply roll, advanced through the process station to form the alloy layer on the substrate and picked and rolled as receiving roll with the alloy layer. As the substrate is advanced through the process station, the alloy layer is at least deposited and/or annealed in various process chambers such as a ALD or CVD or PVD chamber or an electroplating chamber and/or an annealing chamber to form the alloy layer on the substrate. The substrate surface over which the alloy layer is deposited may include one or more material layers such as a so called contact layer including molybdenum. Such finished substrate-alloy layer or substrate-contact layer-alloy layer roll, or base roll, may be used as a base or to manufacture of the above mentioned solar cells and photovoltaic devices by also forming the absorber layer and other layers such as buffer and transparent oxide layers over the base roll in a roll to roll manner.

If the Group IIIA material is Ga metal, the alloy layer may comprise an atomic composition of up to 50% of gallium (Ga) with the balance of ruthenium (Ru) and other impurities, whether inevitable or deliberate. Inevitable impurities are related to the Mo, Ga and Ru sources as well as any impurities from the substrate such as Alkali metals (Na, K, Rb) and transition metals (Sn, Zn, Pb, Ni, Fe, Cu, In, Al, Ce, Cr, Mo, Ti, Nb, Co, Mo) as well as organic residues from the substrate which would increase the carbon content of the alloy layer. Other inevitable impurities are those that might arise from diffusion from any such layer of the back contact which include Alkali metals (Na, K, Rb) and transition metals (Sn, Zn, Pb, Ni, Fe, Cu, In, Al, Ce, Cr, Mo, Ti). Deliberate impurities comprise at least one of Alkali metals (Na, K, Rb) in the form of Metal salts such as metal floruides, chlorides, nitrates or sulfate and transition metals (Sn, Zn, Pb, Ni, Fe, Cu, In, Al, Ce, Cr, Mo, Ti, Nb, Co, Mo). Impurities either deliberate of inevitable should be less than 5% atomic. The alloy layer may comprise one or more Ru—Ga phases or crystals such as RuGa, RuGa₂ and RuGa₃ phases, alone or in various combinations. Furthermore, the Ru—Ga alloy may be a disordered alloy or an ordered alloy such as an intermetallic compound. RuGa crystal has a cubic structure with a preferred crystal orientation of (110); RuGa₃ crystal has a tetragonal structure with a preferred crystal orientation of (220); and RuGa₂ has an orthorhombic crystal structure. However alloys with no preferred crystal orientation, mixed phases including Ga and Ru or its alloys, intermetallics, and sub-stoichiometry phases or phases with impurities may be formed and are herein referred to as alloys without further distinction. The alloy layer may have a mean grain size of preferably less than 250 nm.

In one implementation, an alloy layer may be used as a base for p-type solar absorbers. This alloyed base may function as a diffusion barrier or an ohmic contact for the absorber layer, or both. In another implementation, the alloy layer including Ru and Group IIIA material may be used as a Group IIIA material source for the formation of p-type solar cell absorbers. To function as a Group IIIA material source, an alloy layer with a first composition, i.e., an initial composition of Ru and Group IIIA material, is first formed over a substrate, and then this first composition is transformed into a second composition that is different from the first composition, i.e., a secondary Ru and Group IIIA material composition, during an absorber formation step. For example, if a p-type absorber, such as a CIGS absorber, is formed a portion of the Group IIIA material such as Ga or In metals may diffuse into the absorber layer while it is forming, resulting in a reduction of the Group IIIA component of the Ru—Ga alloy layer composition while contributing to the absorber layer composition.

Reference will now be made to the drawings wherein like numerals refer to like parts throughout. FIG. 3 shows a base sheet 200 to be used for a solar cell or photovoltaic device manufacturing. In one embodiment, the base sheet 200 may comprise an alloy layer 202 formed on a substrate 204 or substrate sheet. The substrate 204 may be a single layer structure including a bottom sheet 204A as a single substrate sheet or a multilayer structure including, for example, a contact layer 204B formed on the bottom sheet 204A. The bottom sheet 204A may be a conductive sheet material such as a stainless-steel foil or an aluminum foil. The contact layer 204B may be a metal layer such as molybdenum (Mo) layer or a metal-nitride, or a multilayer metal film stack such as a Cr/Mo film stack. The alloy layer 202 may be formed on a top surface 205 of the substrate 204, i.e., on top of the bottom sheet 204B or the contact layer 204B if used. The alloy layer 202 comprises Ru and a Group IIIA material such as Ga or In metals. As described above, the alloy layer 202 may be formed by co-depositing Ru and Ga using a Physical Vapor Deposition process such as sputtering, or Atomic Layer Deposition (ALD) or Chemical Vapor Deposition (CVD) or using an electrochemical process such as electroplating. Alternatively, the alloy layer 202 may be formed by depositing a first layer 202A on the top surface 205 of the substrate 204, and then depositing a second layer 202B on the first layer 202A using either a PVD or electrochemical process. In one embodiment, the first layer 202A may be a Ru layer that is electroplated on the top surface 205, and the second layer 202B may be a Ga layer electroplated on the first layer; or the first layer 202A may be a Ga layer and the second layer 202B may be a Ru layer. The thickness of the alloy layer 202 may range between 1 nm and 100 um. If two individual layers 202A and 202B are deposited to form the alloy layer 202, each layer may be a single monolayer or several micrometers in thickness. For example, 10 nm of a Ru layer 202A can be electroplated on the top surface 205, and 43.4 nm of Ga can be electroplated on top of 202A to form a cubic RuGa structure. Alternatively, if 55 nm of Ga is plated on 10 nm of layer 202A, a mixed crystal structure of cubic RuGa and tetragonal RuGa₃ can be formed if appropriate annealing conditions are provided.

Once a stack of Ru and Ga layers is formed, this stack may be annealed at a predetermined temperature range of 100° C. to 650° C. to form the alloy layer 202 including Ru—Ga alloy phases. The preferred annealing temperature for RuGa crystal formation is at least 500° C. The preferred annealing temperature for RuGa₃ crystal formation is between 250° C. and 450° C. RuIn₃ formation may be achieved at temperatures as low as 350° C. However, RuGa₃ and RuGa may preferentially form when both In and Ga are present in layer 202B. The alloy layer 202 may be formed in an inert atmosphere at atmospheric pressures, and temperature ramp conditions may be as high as, but not limited to, 550° C./minute with dwell times ranging from 1 second to several hours.

As will be described more fully below, the stack may also be formed using various combinations by replacing the Ru-layer and Ga-layer with Ru-alloy layer and Ga-alloy layer respectively. The following anneal process forms the Ru—Ga alloy and also adjust the grain size of the alloy crystals, which may be preferably less than 250 nm. The stack may include more than two layers, i.e., multiple layers of Ru and Ga or their alloys. An annealing process in the temperature range of 100° C. to 650° C. may also be applied after a co-deposition process to refine the grain size and alloy phase of the alloy layer 202 and to reduce the mechanical stresses within the alloy layer. Alternatively, co-deposition can be carried out at substrate temperature range of 100° C. to 650° C., more preferably in the temperature range of 250° C. to 500° C., to achieve preferred alloy formation during the co-deposition for the deposition techniques that allow high substrate temperature such as PVD, ALD and CVD.The stack is annealed at a temperature greater than 250° C., more preferably greater than 500° C. to alloy Ru with Ga to form a Ru—Ga alloy thin film.

If sputtering (sputter deposition technique) is used as the PVD process, Ru—Ga co deposition may be made using sputtering targets including Ru and Ga elements. An exemplary sputtering target may be manufactured by: providing a powder comprising particles that collectively comprise Ru and Ga in chemical compositions such as, chlorides, sulfates, oxides, hydroxides, oxyhydroxides, or other Ru—Ga alloys of different compositions; subjecting the powder to one or more of chemical co-precipitation, mechanical alloying, milling, or blending processes to produce a mixed material and consolidating the mixed material to produce a sputter target body having a composition comprising any desired stoichiometry of the Ru—Ga alloy. The consolidation of the processed volume may be performed using one of more of a vacuum hot pressing, hot isostatic pressing, thermal reduction to metal base, thermal sintering, inductive heating/sintering, or energy-assisted sintering processes or any other common metallurgical methods known in the art.

If the alloy layer 202 is formed by sputtering, a stack of layers including Ru and Ga layers; for example, the first layer 202A including Ru may be first deposited on the substrate 204 and the second layer 202B including Ga may be subsequently deposited on the first layer, i.e., a Ru/Ga stack. Both Ru and Ga materials may also be deposited using evaporation, electrodeposition or other deposition methods to form the desired stack. Multilayers comprising the Ru/Ga/Ru/Ga or Ga/Ru/Ga/Ru stacks with layers having varying thicknesses may also be deposited in the same manner, to improve the alloy formation and decreases the diffusion length of the alloy components. The Ru—Ga alloy may also be formed in-situ by evaporation or sputtering of a Ru—Ga alloy target or targets or by the use or a Ru and Ga target. An annealing process in the temperature range of 100° C. to 650° C. may also be applied after a co-deposition process to refine the grain size and alloy phase of the alloy layer 202 and to reduce the mechanical stresses within the alloy layer. Alternatively, co-deposition can be carried out at substrate temperature range of 100° C. to 650° C., more preferably in the temperature range of 250° C. to 500° C., to achieve preferred alloy formation during the co-deposition. The stack is annealed in temperature range of 100° C. to 650° C., more preferably in the temperature range of 250° C. to 500° C., to achieve preferred alloy formation.

Although the sputtering method is the preferred PVD method, Ru layers as well as Ru—Ga layers may be deposited using other PVD techniques such as an e-beam and thermal evaporation techniques. Sputtering may also be the preferred technique of deposition in large scale production due to higher deposition rates and better uniformity. When Ru and Group IIIA material stacks are formed, Ru layers may preferably be deposited from a Ru-target using DC magnetron sputtering technique. Ru thin films with thickness ranging from 5 to 500 nm can be deposited by this technique. In DC magnetron sputtering technique, a magnetic field is used to trap the secondary electrons close to the target. The magnetic field is arranged in such a way that the electrons follow a helical path around the magnetic field lines resulting in more ionizing collisions with neutral gaseous atoms near the target, which leads to the enhancement of the plasma near the target, thus increasing the sputter rate. Several inert gases such as Argon can be used as working gas for generating the plasma. The sputter deposition can be achieved at lower working pressures. The properties of the thin film deposited by sputtering are controlled by the working gas pressure and the sputtering power. The working gas pressure can be in the range of 1 to 30 m Ton and the sputtering power can be in the range of 1 to 4 kW. Similarly, Ru and Ga containing thin films can be co-deposited by DC magnetron sputtering technique from Ru—Ga targets. The target composition will be dependent on the required composition of the thin film and the sputtering rates of each of the elements in the alloy targets. A pulsed DC magnetron sputtering technique can also be used for the deposition of the Ru and Ga containing thin films. In one exemplary target preparation method, powders of Ru and Ga may be mixed in 1:1 atomic ratio, grinded together and heat-treated in an inert atmosphere to form a Ru—Ga metallic alloy sputtering target. Then, a thin film of Ru—Ga alloy is deposited using DC or RF sputtering from this target to form a Ru—Ga alloy layer to function as a contact layer and/or a diffusion barrier layer for a photovoltaic device. An annealing process in the temperature range of 100° C. to 650° C. may also be applied after a co-deposition process to refine the grain size and alloy phase of the alloy layer 202 and to reduce the mechanical stresses within the alloy layer. Alternatively, co-deposition can be carried out at substrate temperature range of 100° C. to 650° C., more preferably in the temperature range of 250° C. to 500° C., to achieve preferred alloy formation during the co-deposition. The stack is annealed in temperature range of 100° C. to 650° C., more preferably in the temperature range of 250° C. to 500° C., to achieve preferred alloy formation A p-type absorber material such as a CIGS absorber layer can be deposited on this Ru—Ga alloy back contact to manufacture a solar cell by any methods commonly known in the prior art.

Ga metal may preferably be electrodeposited from an electroplating solution or electrolyte including Ga-ions. In one exemplary Ga electroplating solution, Ga-ions may be dissolved in aqueous solutions at highly alkaline regime using concentrated strong bases containing hydroxide ions. In a pH range of 9-13, complexing agents such as citrate, tartrate, ethylenediaminetetraacetic acid, ethylenediamine, glycine and the like may be added to the plating solution to help solubilize Ga ions. In an acidic pH range, for example a pH range that is less than 3.5, Ga metal may be plated from acidic solutions containing chloride, sulfamate, sulfate ions. Ga salts may be dissolved in such solutions to provide Ga ions. Ga salts such as Ga-chloride, Ga-sulfate, Ga-sulfamate, Ga-acetate, Ga-carbonate, Ga-nitrate, Ga-perchlorate, Ga-phosphate, Ga-oxide, and Ga-hydroxide can be used to prepare Ga electroplating solutions. In addition to substantially pure Ga electroplating solutions, alloy/compound plating solutions of Cu—Ga, Cu—Ga—In, Cu—In—Ga—Se, Ga—Se, and In—Ga—Se can also be used to electrodeposit Ga-containing layers, i.e., layers containing Ga along with other materials that can be used to form absorber layers. For example, stacks of Ru/Ga, Ru/Ga—Se, Ru/In—Ga—Se, Ru/Cu—Ga, Ru/Cu—Ga—In, and Ru/Cu—In—Ga—Se layers may be formed by first depositing a Ru layer, and then electrodepositing a Ga-containing layer. In the following alloy forming step, by controlling the annealing temperature, Ru—Ga alloy formation is induced while the other elements are made available for the absorber layer.

As mentioned above, in addition to use of Ru—Ga alloy layers as a base in the PV devices, Ru—In alloys may also be utilized as bases in manufacturing of CIGS type solar cells or other p-type photovoltaic cells. If the Group IIIA material is In metal, the alloy layer may comprise an atomic composition of up to 50% of indium (In) with the balance of ruthenium (Ru) and other impurities, whether inevitable or deliberate, with these other impurities essentially the same as discussed above with respect to Ru—Ga alloy layers. Similar to the Ru—Ga alloy formation, a stack of Ru-containing layers and In-containing layers can be deposited on a substrate and then thermally processed or annealed to form a Ru—In alloy layer. In-metal may also be electrodeposited from various In-plating solutions or electrolytes. In-ions may be dissolved in aqueous solutions at highly alkaline regime using concentrated strong bases containing hydroxide ions. In a pH range of 9-13, complexing agents such as citrate, tartrate, ethylenediaminetetraacetic acid, ethylenediamine, glycine and the like may be added to the plating solution to help solubilize In-ions. In the acidic regime, indium may be electroplated from acidic solutions containing chloride, sulfamate, sulfate ions in a pH range less than 3.5. In-salts can be dissolved in such solutions to provide the In-ions. The In-salts such as In-chloride, In-sulfate, In-sulfamate, In-acetate, In-carbonate, In-nitrate, In-perchlorate, In-phosphate, In-oxide, and In-hydroxide can be used. In addition to substantially pure In electroplating solutions, alloy/compound plating solutions of In—Ga, Cu—Ga—In, Cu—In—Ga—Se, In—Se, and In—Ga—Se can be also used to electrodeposit In-containing layers, which also will contain other impurities, whether inevitable or deliberate, with these other impurities essentially the same as discussed above. For example, stacks of Ru/In, Ru/In—Se, Ru/In—Ga—Se, Ru/Cu—In, Ru/Cu—Ga—In, and Ru/Cu—In—Ga—Se can be formed by depositing first a pure Ru layer, and then electrodepositing the In-containing film. In the following alloy forming step, by controlling the annealing temperature, Ru—In alloy formation is induced while the other elements are made available for the absorber layer. In addition to electrodeposition, In-containing films can also be deposited using sputtering and evaporation techniques. Ru—In alloy films can also be formed by co-depositing Ru and In, and optionally Cu, Ga and Se using PVD techniques such as sputtering and evaporation. Again in the following alloy forming step, by controlling the annealing temperature, Ru—In alloy formation is induced while the other elements are made available for the absorber layer. Ru—In alloy layers can be deposited from alloy targets using DC magnetron sputtering techniques. The alloy target composition depends on the required composition of the thin film and the sputtering rates of each of the elements in the alloy targets. Pulsed DC magnetron sputtering can also be used for the deposition of the Ru—In alloy thin films.

In another embodiment, Ru-alloys may be used to form the Ru-containing film, which also will contain other impurities, whether inevitable or deliberate, with these other impurities essentially the same as discussed above. For example, alloys of Ru with Mo, Cr, Ti, Ta, W, Re, Os, Ir, Pt, Au, Hf, Nb, V, Zr, Rh, Co, Ni, Pd, In, Ga, Cu, Se, Te, Al, Sb, and Bi can be deposited in the form of a thin film as the first film on a base. Some exemplary Ru alloys may be Ru—Mo, Ru—Cr, Ru—Ti, Ru—Ta, Ru—W, Ru—Re, Ru—Os, Ru—Ir, Ru—Pt, Ru—Au, Ru—Hf, Ru—Nb, Ru—V, Ru—Zr, Ru—Rh, Ru—Co, Ru—Ni, Ru—Pd, Ru—In, Ru—Ga, Ru—Cu, Ru—Se, Ru—Te, Ru—Al, Ru—Sb, and Ru—Bi. After depositing a film containing one or more of these Ru-alloys on a substrate, a Ga or In-containing film is deposited over the Ru alloy film. Then these two layers are thermally reacted to form a Ru—Ga or Ru—In alloy layer. The alloy layer may be formed on various substrates in CIGS solar cell applications. For example, the substrate can be a sheet of glass, a sheet of metal, an insulating foil or web, or a conductive foil or web.

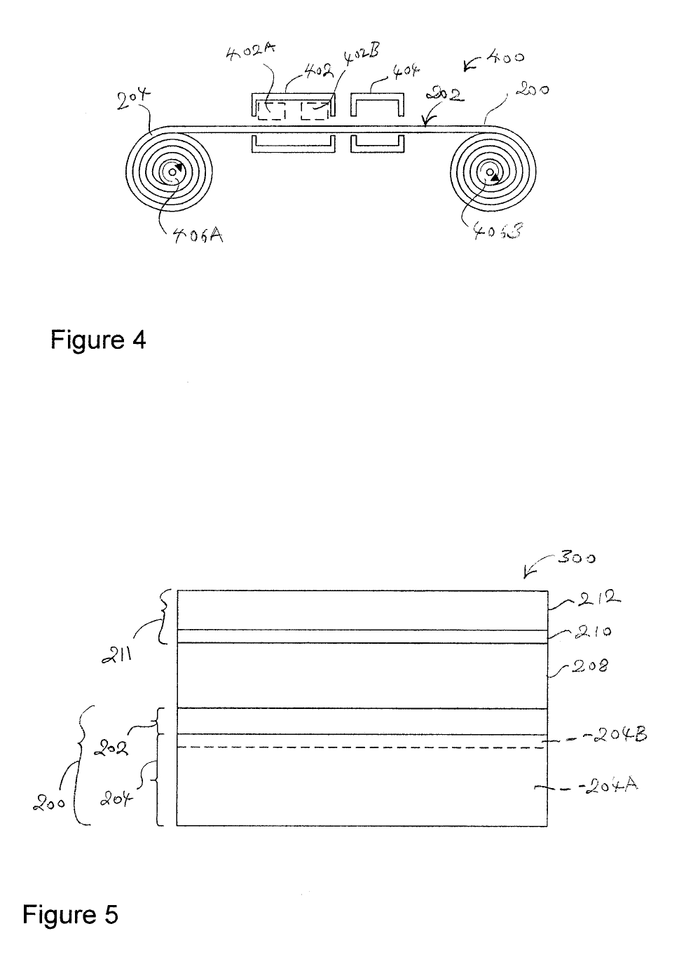

As shown in FIG. 4 the base 200 including the alloy layer 202 may be manufactured using a roll-to-roll base process system 400. The system 400 may include a deposition station 402 to deposit a layer or layers containing Ru and Group IIIA materials and an anneal station 404. Depending on the deposition method, the deposition station 402 may have one more deposition chambers 402A and 402B to deposit the Ru layer and the Group IIIA material layer. As described, Ru and a Group IIIA material such as Ga or In may be deposited as discrete layers with predetermined thickness or co-deposited. Accordingly, in one embodiment, the deposition chamber 402A may be a PVD chamber to deposit the Ru layer and the deposition chamber 402B may be an electroplating chamber to deposit the Group IIIA material such as Ga metal on top of the Ru layer. After depositing Ru and Group IIIA material using the selected process, an anneal process is performed in the anneal chamber to convert the deposited layer into a Ru-Group IIIA alloy layer such as a Ru—Ga alloy layer. During the process, the foil substrate 204 is unrolled from a supply spool 206A, extended through the deposition station 402 and the anneal station 404, and picked up and rolled around a receiving spool 406B as a manufactured base roll. Ru and Group IIIA material is deposited on top of the substrate 204 as the substrate is advanced through the deposition station 402. Deposited material is continuously advanced into the anneal station 404 and the alloy layer 202 is formed on the substrate with the heat treatment. Once the base roll is complete, for example, it may be taken to an absorber station (not shown) to form an absorber layer on the base 200 using this time a roll to roll absorber manufacturing method.

Once a stack of Ru-containing layer and Ga (or In) containing layer is formed using any of the above described methods, the stack is heat treated at high temperature above 250° C., more preferably above 500° C. to alloy Ru with Ga (or In) to form the alloy layer 202.

As shown in FIG. 5, once the base 200 having the alloy layer 202 on the substrate 204 is formed, an absorber layer 208 such as a p-type Group IBIIIAVIA compound absorber layer (CIGS absorber) is formed on the alloy layer 202 or the base 200 including the alloy layer 202. In general, a CIGS absorber layer 208 may be formed using a two-step process including: forming a CIGS precursor layer on the alloy layer 202, and reacting the CIGS precursor at a predetermined reaction temperature (400-650° C.) to transform it to a CIGS absorber layer. Preferably, the precursor layer 208 may be prepared by electroplating Cu/Ga/Cu/In/Se or Cu/In/Cu/Ga/Se absorber precursor stacks over the alloy layer 202. The precursor stacks prepared in this fashion work well as starting precursor material and the rest of the precursor stack is completed by depositing Na and an additional amount of selenium on the stack including Cu, In, Ga and Se layers. Na is added as a dopant material. Solar cells with high efficiencies may be obtained when the Cu/Ga+In and GalGa+In ratios are controlled well and the right amount of Na doping is achieved in the resultant CIGS absorber. A CIGS absorber or absorber precursor may alternatively be formed on the alloy layer 202 by co depositing Cu, In, Ga and Se elements by a PVD co deposition process or a co-electrodeposition process. When such absorber is formed after a PVD co-deposition process, a reaction or heat treatment step may not be needed.

Once the absorber layer 208 is formed, a transparent layer 211 including a buffer layer 210 such as a CdS layer formed on the absorber layer 208 and a transparent conductive oxide layer 212 (TCO layer) such as doped ZnO is formed on the buffer layer to complete a solar cell 300. There may be a conductive terminal (not shown), such as conductive fingers and busbar or conductive grid wires, on the TCO layer to collect the charge generated in the solar cell 300.

Although it was exemplified with a p-type CIGS absorber, the alloy layer 202 may be used as a back contact material for all types of p-type compound semiconductors, such as CdTe and CuZnSnS₄ (CZTS). The alloy layer 202 may form a good ohmic contact to the p-type semiconductor of the absorber layer 208 while also functioning as a diffusion barrier between the substrate 204 and the absorber layer 208. Diffusion barriers are needed to prevent the impurities from diffusing into the absorber layer from the substrate during the manufacturing stages of the solar cells. For example, the alloy layer 202 may be used to prevent the diffusion of iron, chromium and nickel from a stainless steel foil substrate into the absorber layer during the high-temperature anneal step to react Cu, In, Ga and Se to form the CIGS absorber. The alloy layer 202 also prevents diffusion of Se or S species into the stainless substrate.

In one embodiment, the above described process of alloying Ru with Ga or In to form the alloy layer 202 may be adapted to an absorber layer forming process. For example, when adapting the alloying process to the CIGS absorber forming process, the alloying interactions between Ru and Ga or Ru and In may depend on several other parameters. For example, the Ru—Ga reactivity, in other words affinity between Ru and Ga atoms to form preferred Ru—Ga alloy phases, may depend on temperature, the ratio of Ga to Cu, and the ratio of Ga to Se. A CIGS precursor may be formed by forming a precursor stack by depositing multiple films of Cu, In, Ga and Se elements over a Ru layer using PVD or electroplating processes. As will be exemplified below, as the absorber precursor is reacted at selected temperature ranges Ga or In atoms diffuse towards the Ru layer on the substrate and form the alloy layer 202 as the absorber precursor is reacted to form the absorber layer 208. For example, first a 1000 Å thick Cr layer, 5000 Å thick Mo layer on the Cr layer, and then 500 Å thick Ru layer on the Mo layer may be sputter deposited on a stainless steel substrate. Then 2170 Å of Ga may be electroplated on top of the Ru layer surface, and the stack of layers may be annealed for approximately 45 minutes at temperatures between 250° C. and 400° C. This results in an alloy layer having RuGa₃ phase on top of Cr/Mo layers. Cu and In can be electroplated on top of the alloy layer, and then Se may be thermally evaporated on top. The layers may be annealed between 450 and 600° C. for 1 to 60 minutes to form CIGS. During the second anneal, Ga leaves the RuGa₃ phase to form CIGS with the Cu—In—Se layers. The amount of Ga left bound to Ru is dependent on the molar ratio of Ga/Ga+In, Cu/Ga+In, and Ga/Se. The molar ratios of Ga/Ga+In and Cu/Ga+In in the deposited layers should be maintained between a preferred range of 0.3 to 0.6 and 0.7 to 1.1, respectively. The molar ratio of Se/Cu+In+Ga should be maintained above 1. With these molar ratios, and a second annealing temperature above 450° C., the RuGa₃ alloy phase formed in the first anneal will transform into the RuGa alloy phase during the second anneal (during CIGS growth).

The embodiments form Ru—Ga alloys at temperatures as low as 350° C. Using X-Ray Diffraction (XRD) analysis on the samples of Ru—Ga alloys, at least two alloy phases or crystals are identified, namely RuGa₃ (2θ-peak at 39.35° in the XRD spectrum, tetragonal (220)) and RuGa (2θ-peak at 42.45° in the XRD spectrum, cubic (110)), where 2θ is the angle measured by the diffractometer which is 2 times the angle of incidence θ of the x-ray beam. RuGa and RuGa₃ crystals may be formed by manipulating the temperature and the Ga:Ru molar ratio. The crystal structure of the alloy layer may be reversibly transformed between the two alloy crystals, namely RuGa and RuGa₃.

One embodiment provides a method of forming Ru—Ga alloys including at least one of RuGa phase and RuGa₃ phase. It has been observed that ruthenium and gallium preferentially form a first phase or a RuGa phase including RuGa crystals at about 525° C., but when the molar ratio of Ga:Ru increases, the excess Ga forms a second phase or RuGa₃ phase including RuGa₃ crystals. The following Example 1 and Example 2 describe exemplary processes to form RuGa and RuGa₃ phases in the alloy layer in the presence of deposited Ga and Ru materials.

### Example 1

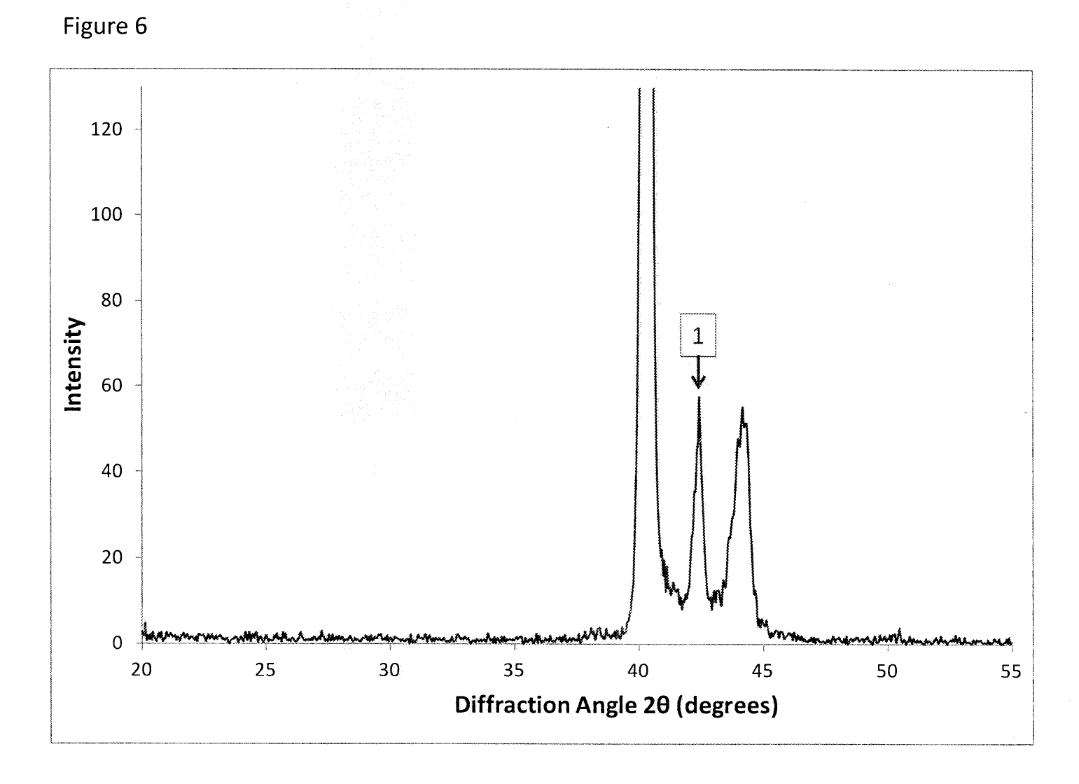

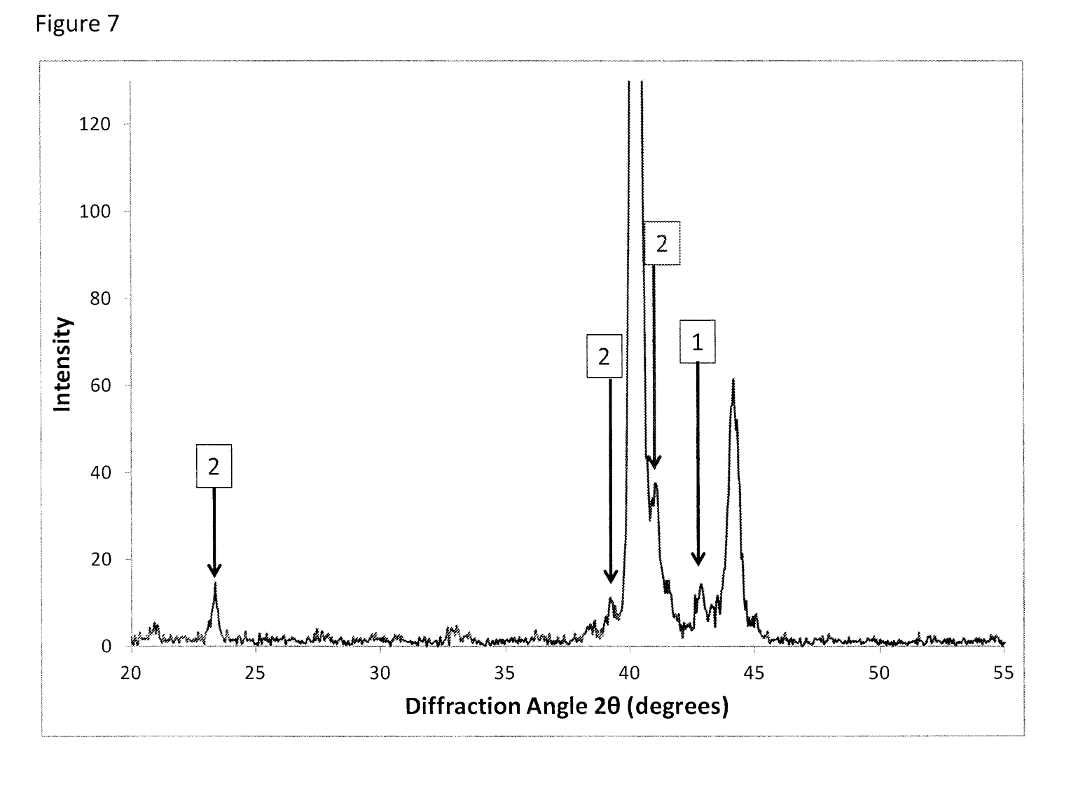

FIG. 6 shows an XRD analysis graph or spectrum (XRD spectrum hereinafter) of a sample including a Ru—Ga alloy. The sample consisted of a 4⅜″×5⅛″ approximately 50 um thick stainless steel foil with a 1000 Å sputtered chromium layer, a 5000 Å sputtered molybdenum layer, and finally a sputtered 500 Å ruthenium layer on top. The alloy was formed by electrodepositing a 600 Å thick Ga film on the 500 Å thick sputter-deposited Ru film and annealing at 526° C. for 20 minutes. A Ga:Ru molar ratio of this Ru—Ga alloy was 1:1. As shown in FIG. 6, the XRD spectrum of this sample has a RuGa peak depicted as ‘1’ (2θ-peak at 42.45°) identifying a RuGa phase. Another sample including a second Ru—Ga alloy was formed by electrodepositing a 4500 Å thick Ga film on a 500 Å thick sputter-deposited Ru film and annealing at 526° C. for 20 minutes. A Ga:Ru molar ratio of this second alloy was 6:1. FIG. 7 shows an XRD spectrum of the second Ru—Ga alloy. As shown in the XRD spectrum, when the molar ratio of Ga:Ru was increased to more than 6:1, the RuGa₃ peaks depicted as ‘2’ (2θ-peaks at 23.40°, 39.35°, and 41.05°) identifying a RuGa₃ phase along with the RuGa peak ‘1’ identifying a RuGa phase were observed in the second Ru—Ga alloy.

### Example 2

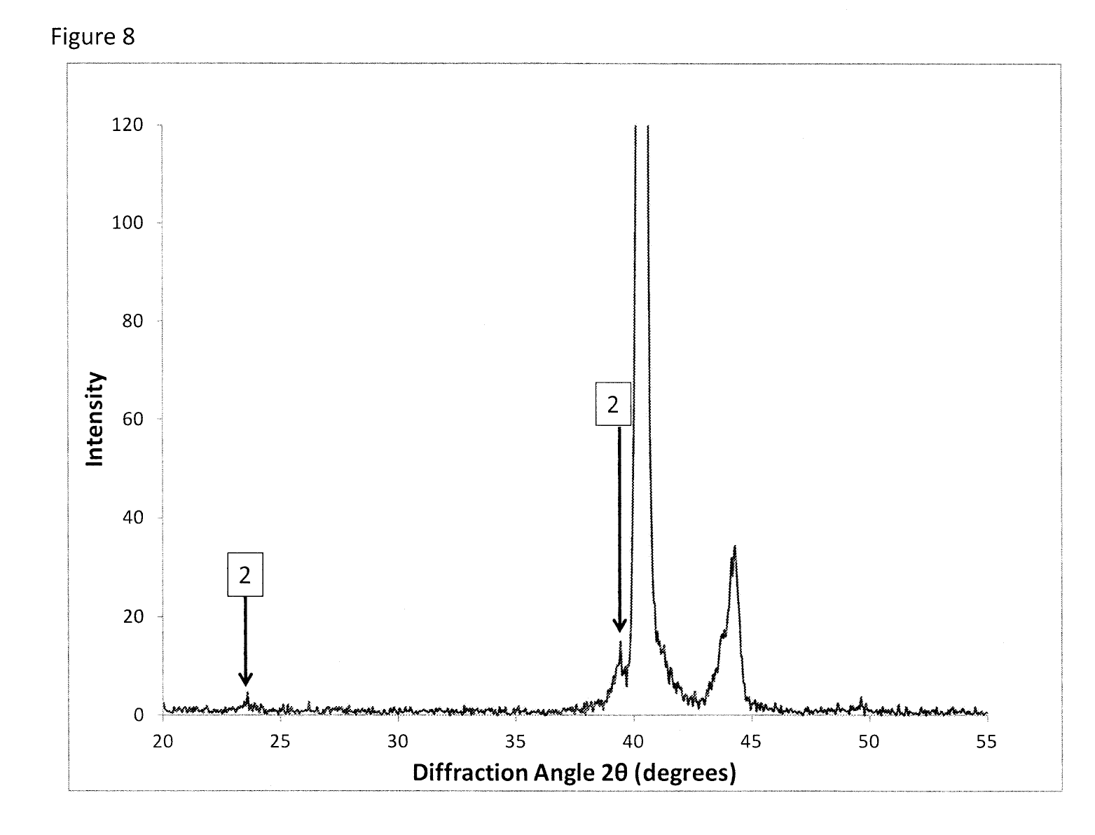

FIG. 8 shows an XRD spectrum of another sample including a Ru—Ga alloy. This sample consisted of a 4⅜″×5⅛″ stainless steel foil with a 1000 Å sputtered chromium layer, a 5000 Å sputtered molybdenum layer, and finally a sputtered ruthenium layer on top. The alloy was prepared by electroplating a 2170 Å thick Ga film on top of a 500 Å thick sputter-deposited Ru film, annealing at 367° C. for 20 minutes. A Ga:Ru molar ratio in the alloy was 3:1. In FIG. 8, the XRD spectrum shows a RuGa₃ peak ‘2’ identifying a RuGa₃ phase formed. At lower temperatures, such as 370° C., only a RuGa₃ phase forms with excess Ga. Therefore, by controlling annealing temperature and the molar ratio of Ga:Ru with or without the excess Ga or Ru, an alloy layer having a pure RuGa phase, a pure RuGa₃ phase, or a mixture of RuGa and RuGa₃ phases can be formed. RuGa₃ forms between room temperature and 367° C. when the molar percentage of deposited Ga is between 3% and 99%. Above 367° C., a RuGa alloy forms exclusively when the molar percentage of deposited Ga is between 1% and 50%. Above 367° C., RuGa and RuGa₃ are produced when the atomic percentage of Ga is between 51% and 99%.

Another embodiment provides a method of forming Ru—Ga alloys in the presence of Cu used in CIGS type cell formation. When gallium is deposited with copper or on top of a copper film, it will form an alloy with copper immediately even below room temperature largely due to the low melting point of Ga element. This Cu—Ga alloy is stable up to about 350° C. Ga atoms diffuses through the Cu-film forming CuGa₂, CuGa, and Cu₂Ga phases depending on the initial Ga:Cu molar ratio. With elevated temperatures, especially above 350° C., Ga atoms diffuse quickly through the Cu-film and begin to react with the ruthenium layer below.

The material phases of Ru—Ga and Ru—In alloys that were observed in XRD analysis were also confirmed by Inductively Coupled Plasma (ICP) measurements, which is an analytical instrument that measures the concentration of any element in solution. It has been observed that Ru metal, Ru—Ga alloy, and Ru—In alloy are insoluble and resistant to hydrochloric acid, nitric acid, sulfuric acid, piranha, and aqua regia etchants. When Ru and Ga are deposited and annealed on stainless steel or Cr/Mo coated stainless steel, the Ru—Ga alloyed layer will lift off the substrate as a fully intact film in a 9:1 nitric: hydrochloric acid etchant. X-Ray Fluorescence Spectroscopy, Energy Dispersive X-Ray Spectroscopy, and XRD all confirmed the composition of the lifted film as Ru and Ga.) Only the gallium that was unalloyed with the Ru will be dissolved in the etchant, and this concentration can be measured by ICP analysis of the used etchant. Similarly, the deposited gallium can be accurately measured by ICP by etching the electroplated gallium film in an identical sample before the Ru—Ga alloy is formed by an annealing process. The amount of indium or gallium alloyed to ruthenium can be calculated from ICP measured thickness values before and after annealing by using equations (i) or (ii), respectively:

In Alloyed to Ru=(Measured Plated In)−(Measured In After Anneal) Equation (i):

Ga Alloyed to Ru=(Measured Plated Ga)−(Measured Ga After Anneal) Equation (ii):

Another embodiment provides a method of forming Ru—Ga and/or Ru—In alloys for the applications in CIGS type solar cells, or provides a method for forming Ru—Ga alloys in the presence of In. Ru and In atoms alloy at temperatures as low as 350° C. However, Ru atoms preferentially alloy to Ga atoms over In atoms. If a Ga-film is deposited on top of a Ru—In alloy film including the RuIn₃ phase, the Ga atoms from the Ga-film diffuse towards the Ru—In alloy film when this film stack including Ga and Ru—In films is annealed at temperatures above 350° C. The Ga atoms diffusing into the Ru—In alloy replace In atoms to form a Ru—Ga alloy including RuGa₃ phase. The displaced indium will segregate to the surface of the alloyed Ru—Ga film.

### Example 3

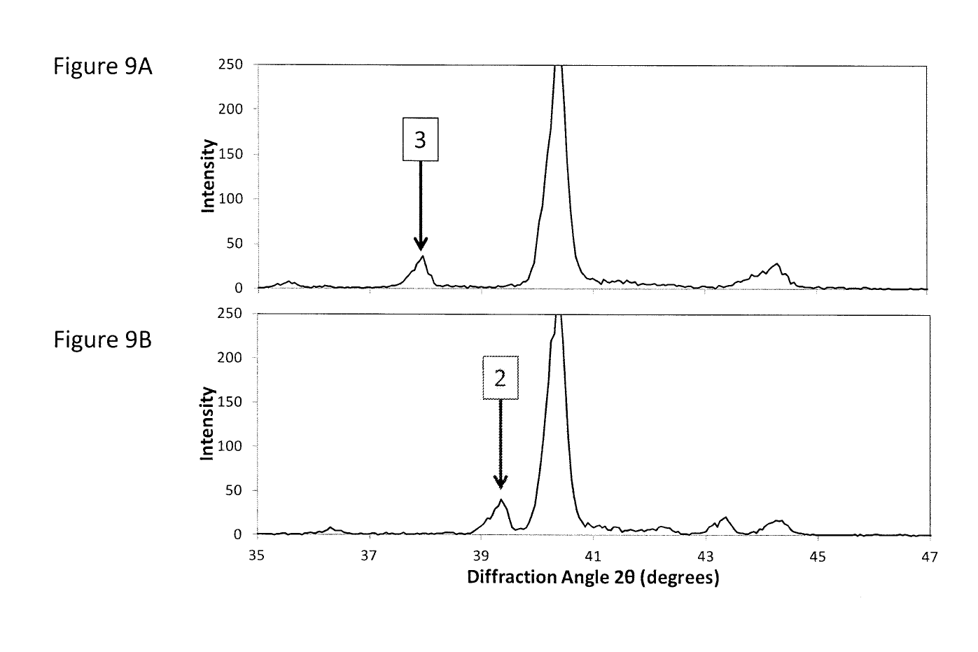

In order to show a Ru—Ga alloy formation in presence of another metal, e.g., In, used in CIGS absorbers, samples were prepared with Ru, Ga and In films. An initial sample including a Ru—In alloy was prepared on a 4⅜″ by 5⅛″ stainless steel foil. The following layers were sputtered sequentially on the foil: 1000 Å chromium, 5000 Å molybdenum, 500 Å ruthenium, and 300 Å copper. To prepare the Ru—In alloy, a 2900 Å thick In film was electrodeposited on the sputter Cr/Mo/Ru/Cu film, and annealing at 526° C. for 20 minutes. As shown in FIG. 9A, in the XRD spectrum of the Ru—In alloy, a peak depicted as ‘3’ (2θ-peak at 37.95°) was identified as a RuIn₃ phase. In the next step, a 2200 Å thick Ga film was electroplated on top of the Ru—In alloy film and annealed at 526° C. to induce Ga atom diffusion into the Ru—In alloy film. The XRD analysis of this sample showed that In atoms in the RuIn₃ phase were displaced by Ga atoms to form a RuGa₃ phase and thereby a Ru—Ga alloy by transformation. FIG. 9B shows the XRD spectrum of this transformed alloy film having a RuGa₃ peak ‘2’ (2θ-peak at 39.35°) indicating a RuGa₃ phase. The displaced indium atoms formed an indium film. It is likely that a Cu—In alloy formed with the 300 Åsputtered copper, however the amount of material was too small to be measured by XRD. The Ru—In and Ru—Ga alloy formations were also confirmed by ICP measurements, which are shown in Table 1 below. As shown in Table 1, in step-1, the thickness of the In-film electrodeposited on the sputter deposited Cr/Mo/Ru/Cu film was measured as 2821 Å by ICP. After the anneal of the In/Ru stack (step-2 in Table 1) to form the Ru—In alloy, ICP only detected 341 Å thick In metal. According to equation (i) given above, the amount of In metal alloyed to Ru metal after the anneal is: 2821 Å−341 Å=2480 Å. Next, Ga film was electrodeposited on the Ru—In alloy film and measured as 2200 Å thick (step-3 in Table 1). During the anneal stage of the Ga-metal/Ru—In alloy stack, as described above, Ga-atoms displaced In-atoms in the Ru—In alloy film to form the RuGa₃ phase. As shown in step-4 in Table 1, The displacement between the Ga and In atoms is shown by an increase of the measured In (now 2677 Å) and a decrease in the measured Ga (now only 66 Å). According to equations (i) and (ii), only 144 Å of In still remained alloyed with Ru metal, and 2134 Å of Ga alloyed with Ru in the form of the RuGa₃ phase by the displacement process. Indicating that Ru—In and Ru—Ga alloys can be simultaneously formed and controlled by tailoring the ration in Ru/In+Ga and In/In+Ga.

TABLE 1

| | | Calculated | | Calculated |
|---|---|---|---|---|
| | ICP | Indium | ICP | Gallium |
| | Measured | Bound to | Measured | Bound to |
| | Indium (Å) | Ru (Å) | Ga (Å) | Ru (Å) |
| Step 1: Indium is | 2821 | 0 | | |
| plated on a | | | | |
| ruthenium film | | | | |
| Step 2: Indium/ | 341 | 2480 | | |
| Ruthenium layers | | | | |
| are annealed | | | | |
| Step 3: Ga is plated | 341 | 2480 | 2200 | 0 |
| Step 4: Gallium/ | 2677 | 144 | 66 | 2134 |
| Indium-Ruthenium | | | | |
| layers are annealed | | | | |

Another embodiment provides a method of forming Ru—Ga alloys in the presence of Cu, In and Se used in CIGS type cell formation. When copper, gallium, indium, and selenium are co-deposited or deposited as discrete layers on a ruthenium film, gallium will react with selenium at temperatures as low as 400° C. to form binary gallium selenides, including GaSe and Ga₂Se₃. In a CIGS precursor, gallium selenides form alongside indium selenides and copper indium selenide up to 400° C. However, as temperatures are increased to 525° C., gallium diffuses to the back contact and reacts with ruthenium to form RuGa and RuGa₃, depending on the Ru:Ga molar ratio. Selenium simultaneously reacts with the rest of the copper and indium to form CuInSe₂, CuSe, and Cu₂Se. In the presence of excess selenium, Ga reacts with selenium, copper, indium, copper selenide, and/or copper indium selenide to form CIGS. Any excess gallium will react with ruthenium to form either a RuGa phase (Ga=1% to 50% atomic) or a mixture of RuGa and RuGa₃ phases (Ga=51% to 99% atomic).

### Example 4

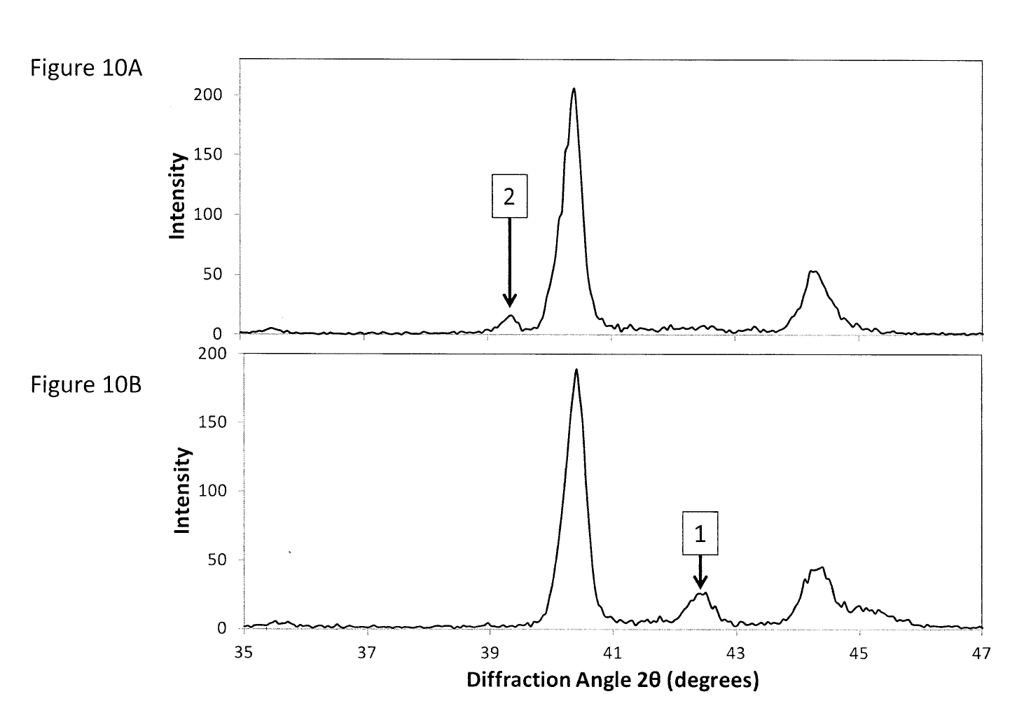

In order to show a Ru—Ga alloy formation in presence of other metals and semi-metals, e.g., Cu, In and Se used in CIGS absorbers, a sample including a substrate/Cr(1000 Å)/Mo(5000 Å)/Ru(500 Å/Cu(1500 Å)/Ga(2500 Å)/Cu(900 Å)/In(3300 Å)/Se (1 um) film stack was prepared where the substrate was a 4⅜″ by 5⅛″ stainless steel foil. Cu, Ga, In films were electroplated on a sputter deposited Cr/Mo/Ru film with a molar Cu/(Ga+In) ratio of 0.8 and a Ga/(Ga+In) ratio of 0.5. Se was evaporation deposited on the Ru/Cu/Ga/In film stack with a Me:Se molar ratio of 1.2, where Me (metal) represents the sum of the copper, gallium, and indium. The layered sample was annealed in an inert atmosphere at 526° C. to form the Ru—Ga alloy in the presence of Cu, In and Se, and the XRD spectrum of the sample is shown in FIG. 10A. A RuGa₃ peak ‘2’ (2θ-peak at 39.35°) indicating a RuGa₃ phase of Ru—Ga alloy is clearly observed.

### Example 5

In order to show a Ru—Ga alloy formation in the presence of other metals and semi-metals, e.g., Cu, In and Se used in CIGS absorbers, another sample including a substrate/Cr/Mo/Ru/Cu/Ga/Cu/In/Se film stack was prepared and annealed as described in Example 4 to form a RuGa₃ alloy. Another 1 um of Se was evaporated onto the annealed stack such that the Me:Se molar ratio was changed from 1.2 to 0.6, where Me (metal) represents the sum of the copper, gallium, and indium. The sample was annealed again in an inert atmosphere at 526° C. to form the Ru—Ga alloy in the presence of Cu, In and Se. Due to the increased amount of Se material in this sample during the second annealing stage, the extra Se atoms pulled Ga atoms from the RuGa₃ phase that had formed in the first anneal step. As Ga atoms left the RuGa₃ phase to combine with Se atoms, the RuGa₃ phase was transformed into a RuGa phase. The XRD spectra in FIG. 10B shows a RuGa peak ‘1’ (2θ-peak at)42.45°) indicating that a RuGa phase of the Ru—Ga alloy formed in Se rich conditions.

Taking advantage of the reaction kinetics of Cu—Ga—In—Se alloying on a ruthenium-coated substrate (Examples 4 and 5), a Ru—Ga alloy with the RuGa₃ phase may be used as a Ga source for CIGS formation when used with copper, indium, and selenium containing layer(s).

### Example 6

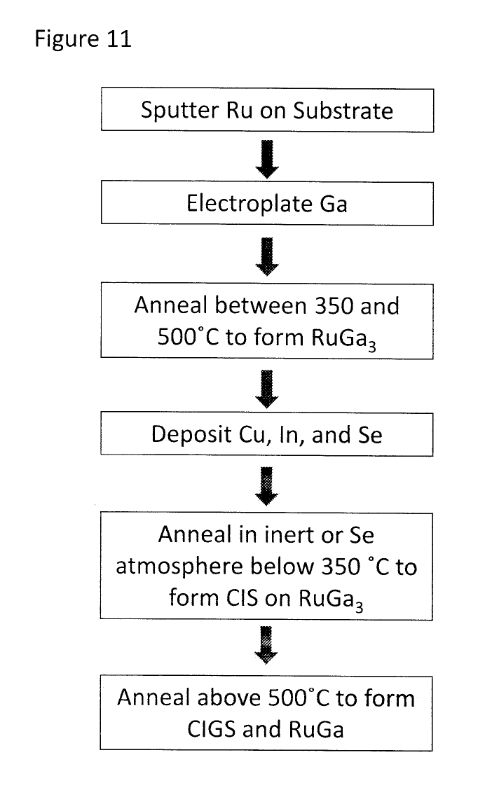

Ru—Ga alloy films can be used as a Group IIIA material source for CIGS formation by forming a RuGa₃ alloy first. A Ga-film may be electroplated onto a Ru-coated substrate at a molar ratio of 3:1 (Ga:Ru) and annealed between 350° C. and 500° C. for at least 10 minutes to form a Ru—Ga alloy including RuGa₃ phase. Next, copper, indium, and selenium films may be electroplated, evaporated, or sputter deposited as discrete layers or by co-deposition on top of the Ru—Ga alloy to form a substrate/Ru—Ga alloy/Cu/In/Se film stack. This film stack may be annealed at low temperature (below 350° C.) in either an inert atmosphere or with a reactive H₂Se and/or H₂S vapor to form a crystalline Cu—In—Se/S (CIS) material on top of the RuGa₃ layer. Once the CIS has been formed, the sample may be heated above 500° C. to convert the RuGa₃ phase to a RuGa phase and supply the CIS layer with Ga. As the RuGa₃ phase transitions into a RuGa phase, Ga atoms diffuse into CIS to form CIGS on the Ru—Ga alloy film. A process flow for the Example 6 is illustrated in FIG. 11.

### Example 7

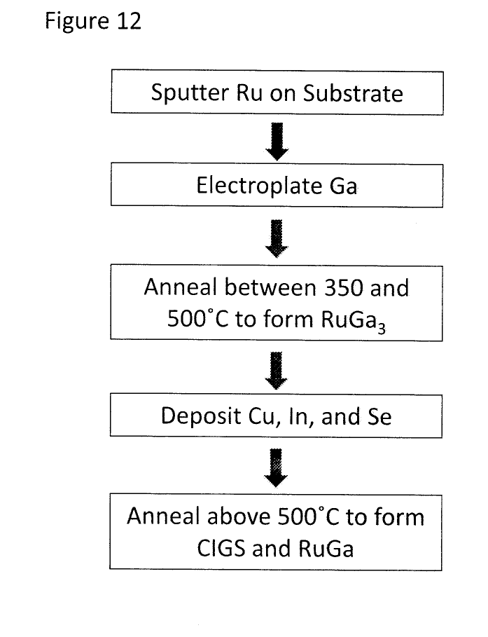

Ru—Ga films can also be used as a Group IIIA source for CIGS formation from an unreacted Cu—In—Se containing film(s). A Ru—Ga alloy including the RuGa₃ phase may be formed as described in Example 8. After the alloy had been formed, Cu, In, and Se may be electroplated, evaporated, or sputtered as discrete layers or by co-deposition on top of the Ru—Ga alloy. The Ru—Ga alloy/Cu/In/Se film stack may then be annealed above 500° C. to simultaneously form CIGS as Ga is rejected from the RuGa₃ phase. The end product is a CIGS film on top of a Ru—Ga alloy (RuGa phase) back contact. The process flow for Example 7 is shown in FIG. 12.

These examples illustrate that we may use a Ru-Group IIIA alloy as a Group IIIA material source for the formation of a p-type solar absorbers. The first Ru-Group IIIA alloy with a first Ru-Group IIIA phase may be initially formed and later transformed into a second Ru-Group IIIA phase as a way to release the Group IIIA element into the p-type absorber as the absorber is formed on the Ru-Group IIIA alloy layer.

In addition to Ga and In, Al can also be alloyed with Ru to form Ru—Al alloy thin films. Such thin films can also be used as an ohmic back contact or diffusion barrier in the formation of CIGS type solar cells. Using the methods described above, CIGS type solar cells having Ru, RuGa, and RuGa₃ as an ohmic contact or base may be manufactured by controlling the Ga:Cu and (Cu+In+Ga):Se molar ratio during CIGS. Cell efficiencies of up to 15.1% on 25 cm² devices may be achieved using RuGa as the bottom contact. Furthermore the formation of RuGa₂ and the transformation to other combinations of the alloy layer or transformation of other alloy layers to RuGa₂ is also considered as a possible alloy phase in this application.

Although certain preferred embodiments are described herein, modifications thereto will be apparent to those skilled in the art.

We claim:

1. An apparatus that provides a thin film solar cell base structure for a photovoltaic device, comprising:
a conductive substrate, wherein the conductive substrate is a sheet shaped substrate including an upper surface;
a ruthenium-Group IIIA alloy layer formed over the upper surface of the conductive substrate, the ruthenium-Group IIIA alloy layer including ruthenium (Ru) and a Group IIIA material; and
an absorber layer foHned over the ruthenium-Group IIIA alloy layer, thereby creating the thin film solar cell base structure.

2. The apparatus of claim 1, wherein the Group IIIA material is gallium (Ga).

3. The apparatus of claim 1, wherein the Group IIIA material is indium (In).

4. The apparatus of claim 1 further comprising a contact layer positioned between the conductive substrate and the ruthenium-Group IIIA alloy layer.

5. The apparatus of claim 4 further comprising a transparent layer formed on the absorber layer, wherein the transparent layer includes a buffer layer formed on the absorber layer and a transparent conductive layer formed on the buffer layer.

6. The apparatus of claim 5, wherein the conductive substrate is one of a stainless steel foil, an aluminum foil and a polymer foil coated with a Mo metallic conductor.

7. The apparatus of claim 6, wherein the absorber layer is a Group IBIIIAVIA compound semiconductor.

8. The apparatus of claim 1, wherein the ruthenium-Group IIIA alloy layer provides an ohmic contact.

9. A apparatus of claim 1, wherein the ruthenium-Group IIIA alloy layer provides a diffusion barrier.

10. A apparatus of claim 1, wherein the ruthenium-Group IIIA alloy provides a diffusion barrier and an ohmic contact.

11. A method of manufacturing a photovoltaic device, comprising:
providing a conductive substrate, wherein the conductive substrate is a sheet shaped substrate including an upper surface;
forming a ruthenium-Group IIIA alloy layer over the upper surface of the conductive substrate, the ruthenium-Group IIIA alloy layer including ruthenium (Ru) and a Group IIIA material;
forming a CIGS absorber layer over the ruthenium-Group IIIA alloy layer; and
reacting the CIGS absorber layer to form the photovoltaic device.

12. The method of claim 11, wherein the step of forming the ruthenium-Group IIIA alloy layer uses a PVD or ALD or CVD process.

13. The method of claim 11, wherein the step of forming the ruthenium-Group IIIA alloy layer co-deposits the ruthenium and the Group IIIA material using a PVD or ALD or CVD process.

14. The method of claim 11, wherein the step of forming the ruthenium-Group IIIA alloy layer comprises:
co-depositing the ruthenium and the Group IIIA material using a PVD or ALD or CVD process; and
annealing the co-deposited film in the temperature range of 100° C. to 650° C. to form the preferred ruthenium-Group IIIA alloy layer.

15. The method of claim 11, wherein the step of forming the ruthenium-Group IIIA alloy layer co-deposits the ruthenium and the Group IIIA material using a PVD or ALD or CVD process with the substrate temperature in the range of 100° C. to 650° C. to form the preferred ruthenium-Group IIIA alloy layer.

16. The method of claim 11, wherein the step of forming the ruthenium-Group IIIA alloy layer comprises:
depositing a film stack over the upper surface of the substrate using a PVD or ALD or CVD process, wherein the film stack includes at least one ruthenium film and a Group MA material film; and
annealing the film stack in the temperature range of 100° C. to 650° C. to form the preferred ruthenium-Group IIIA alloy layer.

17. The method of claim 11 further comprising forming a contact layer between the conductive substrate and the ruthenium-Group III alloy layer.

18. The method of claim 11, wherein the step of forming the ruthenium-Group IIIA alloy layer uses an electroplating process.

19. The method of claim 11, wherein the step of forming the ruthenium-Group IIIA alloy layer co-deposits the ruthenium and the Group IIIA material using an electroplating process.

20. The method of claim 11, wherein the step of forming the ruthenium-Group IIIA alloy layer comprises:
co-depositing the ruthenium and the Group IIIA material using an electroplating process; and
annealing the co-deposited film in the temperature range of 100° C. to 650° C. to form the preferred ruthenium-Group IIIA alloy layer.

21. The method of claim 11, wherein the step of forming the ruthenium-Group IIIA alloy layer comprises:
electroplating a film stack over the upper surface of the substrate, wherein the film stack includes at least one ruthenium film and a Group IIIA material film; and
annealing the film stack in the temperature range of 100° C. to 650° C. to form the preferred ruthenium-Group IIIA alloy layer.

22. The method of claim 11, wherein the step of forming the ruthenium-Group IIIA alloy layer uses both electroplating and PVD, ALD or CVD processes.

23. The method of claim 11, wherein the step of forming the ruthenium-Group IIIA alloy layer comprises:
depositing a film stack over the upper surface of the substrate using a PVD or ALD or CVD process, wherein the film stack includes at least one ruthenium film and a Group IIIA material film;
electroplating a film stack over the top of the film stack deposited using a PVD process, wherein the film stack includes at least one ruthenium film and a Group IIIA material film; and
annealing the film stack in the temperature range of 100° C. to 650° C. to form the preferred ruthenium-Group IIIA alloy layer.

24. The method of claim 11, wherein the Group IIIA material is gallium (Ga).

25. The method of claim 11, wherein the Group IIIA material is indium (In).

26. The method of claim 11, wherein the sheet shaped substrate is a continuous substrate extending between a supply roll and a receiving roll, and wherein the step of forming the ruthenium-Group IIIA alloy layer is performed in a roll-to-roll manner.

27. A roll to roll method of manufacturing a thin film solar cell base structure, comprising:
providing a conductive substrate having a top surface, wherein the conductive substrate is a sheet shaped substrate having a top surface;
advancing the conductive substrate through a process station; and
forming a ruthenium-Group IIIA alloy layer over the top surface of the conductive substrate as the substrate advanced through the process station, to create the thin film solar cell base structure, the alloy layer including ruthenium (Ru) and a Group IIIA material.

28. The method of claim 27, wherein the step of forming uses a PVD chamber as the process station and the step of forming the ruthenium-Group IIIA alloy layer uses a PVD process in the PVD chamber.

29. The method of claim 27, wherein the step of forming uses a PVD chamber as the process station and the step of forming the ruthenium-Group IIIA alloy layer co-deposits the ruthenium and the Group IIIA material using a PVD process in the PVD chamber.

30. The method of claim 27, wherein the step of forming uses a PVD chamber as the process station, wherein the step of forming the ruthenium-Group IIIA alloy layer co-deposits the ruthenium and the Group IIIA material using a PVD process in the PVD chamber and wherein substrate temperature is in the temperature range of 100° C. to 650° C. to form the preferred ruthenium-Group IIIA alloy layer in the PVD chamber.

31. The method of claim 27, wherein the step of forming uses a PVD chamber and an anneal chamber as the process station and wherein the step of forming the ruthenium-Group IIIA alloy layer comprises:
depositing a film stack over the upper surface of the substrate using a PVD process in the PVD chamber, wherein the film stack includes at least one ruthenium film and a Group IIIA material film; and
annealing the film stack in the anneal chamber in the temperature range of 100° C. to 650° C. to form the preferred ruthenium-Group IIIA alloy layer.

32. The method of claim 31 wherein the at least one ruthenium film has greater than 1% atomic ruthenium therein.

33. The method of claim 27, wherein the step of forming uses an electroplating chamber as the process station and wherein the step of forming the ruthenium-Group IIIA alloy layer uses an electroplating process in the electroplating chamber.

34. The method of claim 27, wherein the step of forming uses an electroplating chamber as the process station and wherein the step of forming the ruthenium-Group IIIA alloy layer co-deposits the ruthenium and the Group IIIA material using an electroplating process in the electroplating chamber.

35. The method of claim 27, wherein the step of forming uses an electroplating chamber and an anneal chamber as the process station and the step of forming the ruthenium-Group IIIA alloy layer comprises:
electroplating a film stack over the upper surface of the substrate in the electroplating chamber, wherein the film stack includes at least one ruthenium film and a Group IIIA material film; and
annealing the film stack in the annealing chamber in the temperature range of 100° C. to 650° C. to form the preferred ruthenium-Group IIIA alloy layer.

36. The method of claim 35 wherein the at least one ruthenium film has greater than 1% atomic ruthenium therein.

37. The method of claim 27, wherein the step of forming uses a PVD, ALD or CVD chamber, an electroplating chamber and an anneal chamber as the process station and the step of forming the ruthenium-Group IIIA alloy layer comprises:
depositing a film stack over the upper surface of the substrate using a PVD, ALD or CVD process in the deposition chamber, wherein the film stack includes at least one ruthenium film and a Group IIIA material film;
electroplating a film stack over the upper surface of the substrate in the electroplating chamber, wherein the film stack includes at least one ruthenium film and a Group IIIA material film; and
annealing the film stack in the annealing chamber in the temperature range of 100° C. to 650° C. to form the preferred ruthenium-Group IIIA alloy layer.

38. The method of claim 27, wherein the Group IIIA material is gallium (Ga).

39. The method of claim 27, wherein the Group IIIA material is indium (In).

40. The method of claim 27 further comprising forming an intermediate layer on the top surface prior to forming the ruthenium-Group IIIA alloy layer.

41. The method of claim 40, wherein the intermediate layer includes molybdenum.

42. An ruthenium alloy sheet material comprising, by molar percentage:
1-50% of gallium (Ga);
no more than 5% of any other impurity; and
a remaining molar percentage of ruthenium (Ru).

43. The ruthenium alloy sheet material of claim 42, wherein alloy grains of the ruthenium alloy sheet material have a mean grain size of less than 250 nm in diameter.

44. The ruthenium alloy sheet material of claim 43, wherein a thickness of the ruthenium alloy sheet material is between 1 nm-1000 nm.

45. The ruthenium alloy sheet material of claim 42, wherein a thickness of the ruthenium alloy sheet material is between 1 nm-1000 nm.

46. The ruthenium alloy sheet material of claim 42, wherein the ruthenium alloy sheet material includes a first alloy phase, wherein the first alloy phase is RuGa material.

47. The ruthenium alloy sheet material of claim 46, wherein the ruthenium alloy sheet material includes 1% to 100% RuGa material and 0% to 99% Ru.

49. The ruthenium alloy sheet material of claim 46, wherein the ruthenium alloy sheet material further includes a first alloy phase, wherein the first alloy phase is RuGa₂ material.

50. The ruthenium alloy sheet material of claim 49, wherein the ruthenium alloy sheet material includes 1% to 100% RuGa₂ material and 0% to 99%Ru.

51. The ruthenium alloy sheet material of claim 42, wherein the ruthenium alloy sheet material includes a first alloy phase, wherein the first alloy phase is RuGa₃ material.

52. enium alloy sheet material of claim 51 wherein the ruthenium alloy sheet material includes 1% to 100% RuGa₃ material and 0% to 99% Ru.

53. The ruthenium alloy sheet material of claim 42, wherein the ruthenium alloy sheet material includes a first alloy phase and a second alloy phase, wherein the first alloy phase is RuGa material and the second alloy phase is RuGa₂ material.

54. The ruthenium alloy sheet material of claim 6, wherein a ratio of the first alloy phase to the second alloy phase is in the range of 1 to 99%.

55. The ruthenium alloy sheet material of claim 54, wherein the ruthenium alloy sheet material includes 1% to 99% RuGa material, 1% to 99% RuGa₂ material and 0% to 98% Ru.

56. The ruthenium alloy sheet material of claim 42, wherein the ruthenium alloy sheet material includes a first alloy phase and a second alloy phase wherein the first alloy phase is RuGa material and the second alloy phase is RuGa₃ material.

57. The ruthenium alloy sheet material of claim 56, wherein a ratio of the first alloy phase to the second alloy phase is in the range of 1 to 99%.

58. The ruthenium alloy sheet material of claim 57, wherein the ruthenium alloy sheet material includes 1% to 99% RuGa material, 1% to 99% RuGa₃ material and 0% to 98% Ru.
